(19) United States
(12) Patent Application Publication
(10) Pub. No.: US 2008/0169089 A1
(43) Pub. Date: Jul. 17, 2008

(54) HEAT SINK ASSEMBLY

(75) Inventors: WEI-LE WU, Shenzhen (CN); CHUN-CHI CHEN, Tu-Cheng (TW)

Correspondence Address: PCE INDUSTRY, INC.;ATT. CHENG-JU CHIANG, 458 E. LAMBERT ROAD, FULLERTON, CA, 92835, US

(73) Assignee: FOXCONN TECHNOLOGY CO., LTD., Tu-Cheng (TW)

(21) Appl. No.: 11/623,299

(22) Filed: Jan. 15, 2007

(51) Int. Cl. H05K 7/20

(52) U.S. Cl. 165/104.33; 165/80.3; 361/700

(57) ABSTRACT

A heat sink assembly for a heat-generating electronic component includes a base (12), a shell mounted on the base, and a plurality of heat exchangers (11, 13, 15) mounted on the base and surrounded by the shell. The heat exchangers comprise heat conducting plates (110,130, 150) extending from the base, cores (112, 132, 152) formed on tops of the heat conducting plates and a plurality of fins (114, 134, 154) arranged about the cores. A plurality of heat pipes (20) connects the base and the cores of the heat exchangers for transferring heat from the base to the fins for dissipation.

### BACKGROUND OF THE INVENTION

1. Field of the Invention

This invention generally relates to cooling devices such as heat exchangers and, particularly, to a heat sink assembly having heat pipes for cooling heat-generating electronic components.

2. Description of Related Art

In various industries, such as in the computer industry, there is a need for low cost, high performance heat exchangers to cool heat-generating electronic components such as microprocessors or power chips. Many microprocessors/power chips create so much heat that they can be irreparably damaged if the heat is not removed. Consequently, heat exchangers employing heat sinks have been used to absorb the heat away from these components and disperse the heat into the atmosphere. The present invention is directed to improvements in such heat sink assemblies.

### SUMMARY OF THE INVENTION

The present invention relates to a heat sink assembly for a heat-generating electronic component. The heat sink assembly includes a base, a shell mounted on the base, and a plurality of heat exchangers mounted on the base and surrounded by the shell. The heat exchangers comprise heat conducting plates extending from the base, cores formed on tops of the heat conducting plates and a plurality of fins extending radially and curvedly from the cores. A plurality of heat pipes connects the base and the cores of the heat exchangers for transferring heat from the base to the fins for dissipation of the heat to atmosphere.

Other advantages and novel features of the present invention will become more apparent from the following detailed description of preferred embodiment when taken in conjunction with the accompanying drawings, in which:

### BRIEF DESCRIPTION OF THE DRAWINGS

Many aspects of the present device can be better understood with reference to the following drawings. The components in the drawings are not necessarily drawn to scale, the emphasis instead being placed upon clearly illustrating the principles of the present device. Moreover, in the drawings, like reference numerals designate corresponding parts throughout the several views.

FIG. 1 is an assembled view of a heat sink assembly in accordance with a preferred embodiment of the present invention;

FIG. 2 is an exploded, isometric view of the heat sink assembly of FIG. 1;

FIG. 3 is an isometric view of a heat sink of the heat sink assembly of FIG. 1, but shown from another aspect; and

FIG. 4 is a front view of the heat sink of the heat sink assembly of FIG. 2.

### DETAILED DESCRIPTION OF THE INVENTION

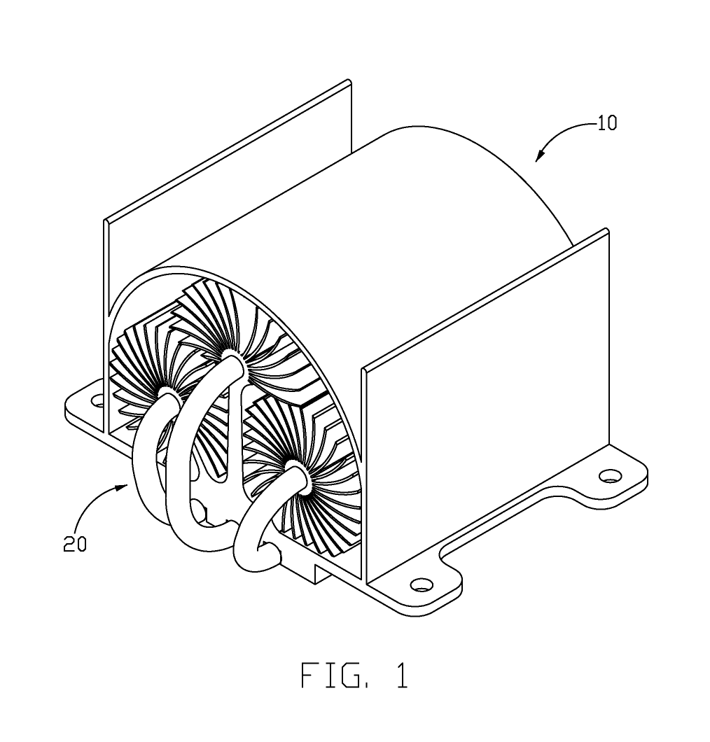

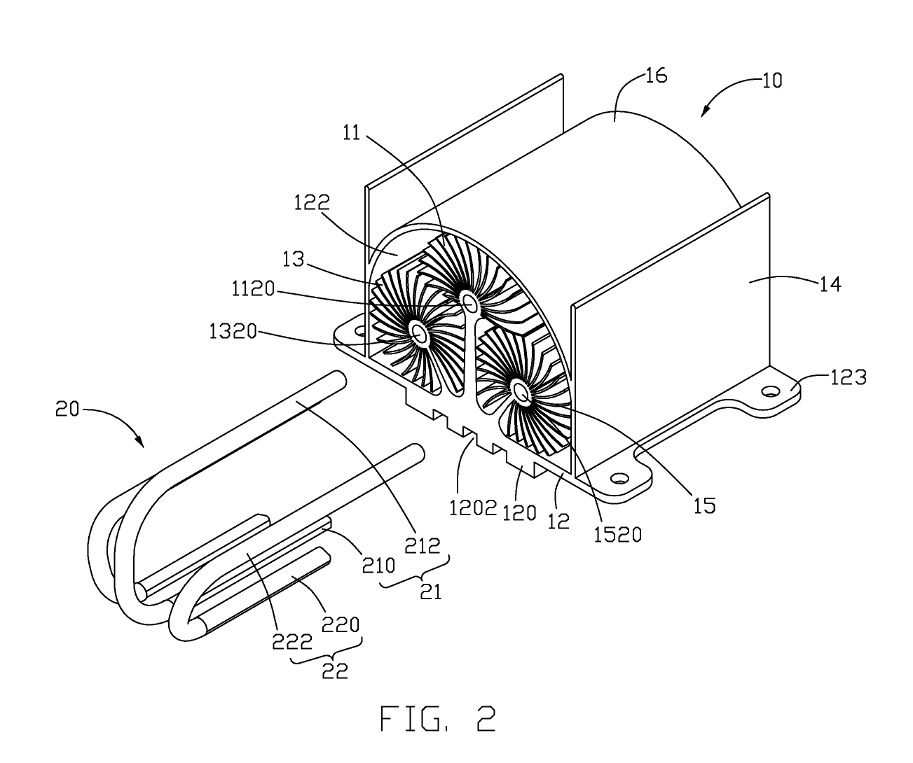

Referring to FIGS. 1-2, a heat sink assembly in accordance with a preferred embodiment of the present invention is used for being mounted to a heat-generating electronic element, such a CPU (not shown), to dissipate heat therefrom. The heat sink assembly comprises an integral heat sink 10 and a heat pipe assembly 20 assembled to the heat sink 10.

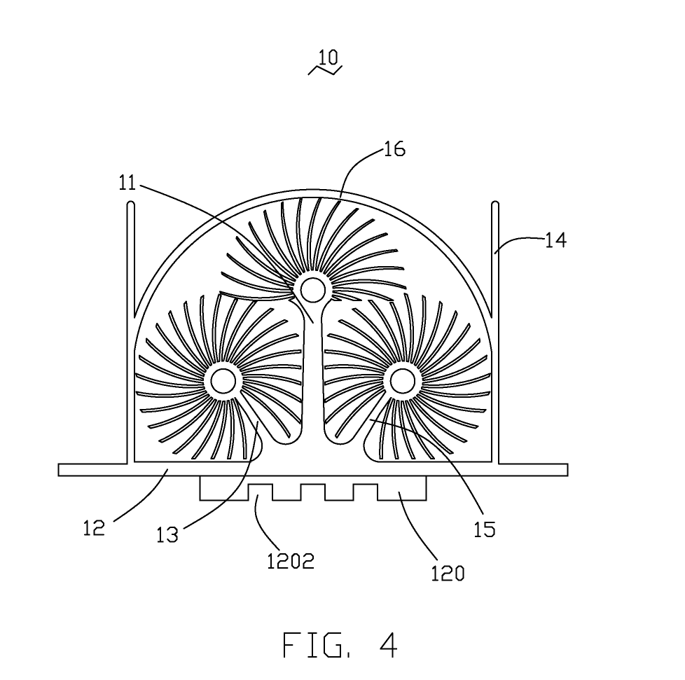

The heat sink 10 is integrally formed by aluminum extrusion and has a base 12. A protrusion block 120 is formed on a bottom surface of the base 12 for contacting with the CPU. The block 120 defines three grooves 1202 therein. Four ears 123 extend outwardly and horizontally from corners of the base 12 and provide passages (not labeled) for fasteners (not shown) to extend therethrough to mount the heat sink assembly on the CPU which is mounted on a printed circuit board (not shown). A pair of lateral plates 14 extend perpendicularly upwardly from a top surface of the base 12. An arched cover 16 connects the two plates 14 at middle portions thereof, whereby a C-shaped shell (not labeled) is formed by the cover 16 and lower portions of the plates 14. Also referring to FIG. 4, a top edge of the cover 16 is in alignment (i.e., the same level) with top edges of the plates 14. Three heat exchangers 11, 13, 15 are formed from the base 12 and received in a space 122 defined by the C-shaped shell. The space 122 has two opposite open ends.

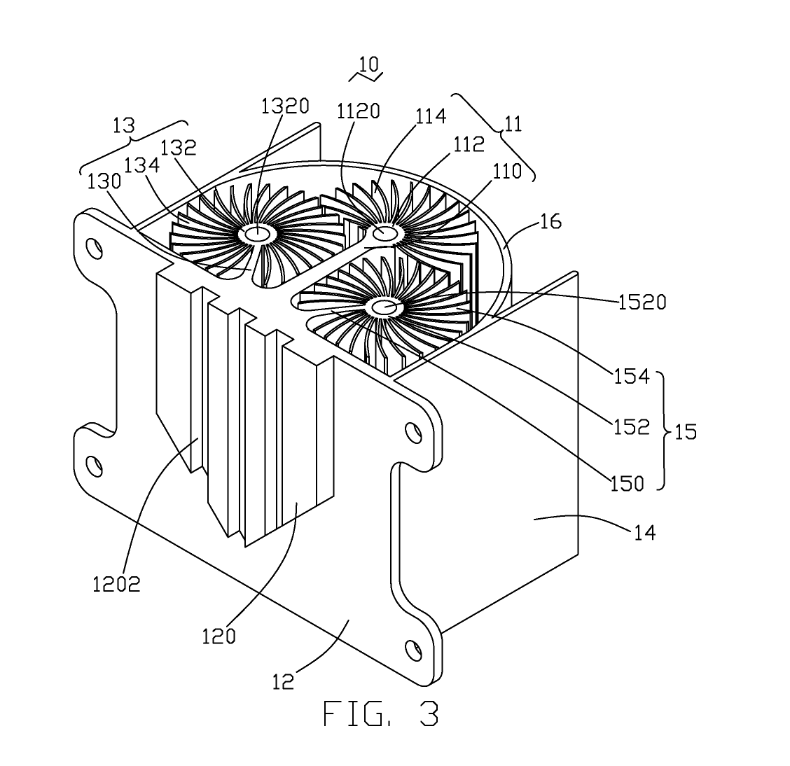

Also referring to FIG. 3, each of the heat exchangers 11, 13, 15 comprises a heat conducting plate 110, 130, 150 extending upwardly from the base 12, a cylindrical core 112, 132, 152 formed on a top of the heat conducting plate 110, 130, 150 and a set of curved fins 114, 134, 154 arranged about the core 112, 132, 152. Each heat conducting plate 110, 130, 150 extends through the space 122 of the heat sink 10 from a front open end to a rear open end thereof. The heat conducting plate 110 is located perpendicularly at a center of the base 12, and the heat conducting plates 130, 150 are slantwise, symmetrically arranged at flanks of the heat conducting plate 110 in such a manner that two neighboring heat conducting plates 110, 130 and 110, 150 form an acute included angle therebetween. The heat conducting plates 130, 150 have the same height which is shorter than that of the heat conducting plate 110. The core 112 of the heat exchanger 11 is located above the cores 132, 152 of the heat exchangers 13, 15. Each of the cores 112, 132, 152 has a central axle (not labeled) parallel to each other and defines a central cavity 1120, 1320, 1520 for insertion of the heat pipe assembly 20. The sets of fins 114, 134, 154 are radially and curvedly extended outwards from the cores 112, 132, 152 of the heat exchangers 11, 13, 15, respectively. The sets of fins 114, 134, 154 are curved in their respective similar directions. The set of fins 134 of the heat exchanger 13 and the set of fins 154 of the heat exchanger 15 are symmetrical and mirror image about the heat conducting plate 110 of the heat exchanger 11, which means that the fins 134 are curved in a clockwise direction while the fins 154 are curved in an anti-clockwise direction. The fins 114 are located above the fins 134, 154. The fins 114 are partly cut away to prevent the fins 114 from interfering with the fins 134, 154. An outer periphery surface of each set of fins 114, 134, 154 is substantially arranged in a cylindrical outline.

Referring to FIG. 2 again, the heat pipe assembly 20 comprises a first heat pipe 21 and a pair of second heat pipes 22 symmetrically slantwise arranged at flanks of the first heat pipe 21. Each of the first and second heat pipes 21, 22 has a U-shaped configuration and comprises an evaporating portion 210, 220 received in the corresponding groove 1202 of the base 12 of the heat sink 10, and a condensing portion 212, 222, parallel to the evaporating portion 210, 220 and engaged in the corresponding cavity 1120, 1320, 1520 of the heat exchanger 11, 13, 15. The evaporating portions 210, 220 of the first and second heat pipes 21, 22 have flat bottoms in order to directly contact with the CPU. A perpendicular distance between the evaporating portion 210 and the condensing portion 212 of the first heat pipe 21 is larger than a perpendicular distance between the evaporating portion 220 and the condensing portion 222 of the second heat pipe 22.

In addition to the integral extrusion of aluminum, alternatively, the heat sink 10 in accordance with the present invention may be made by firstly forming the heat exchangers 11, 13, 15 individually, and then soldering the heat exchangers 11, 13, 15 onto the base 12.

In operation, heat generated by the CPU is absorbed by the base 10 and the evaporating portions 210, 220 of the heat pipe assembly 20, and immediately and simultaneously transferred to the cores 112, 132, 152 of the three heat exchangers 11, 12, 13 via the condensing portions 212, 222 of the heat pipe assembly 20 and the heat conducting plates 110, 130, 150 of the heat exchangers 11, 12, 13. The heat on the cores 112, 132, 152 is subsequently transferred to the fins 114, 134, 154 of the heat exchangers 11, 13, 15 for being dissipated to atmosphere. A system fan (not shown) provides an airflow though the fins 114, 134, 154, thereby enhancing a rate of heat dissipation. The shell of the heat sink 10 prevents the airflow flowing through the space 122 from leaving therefrom. Accordingly, the airflow flowing through the space 122 can have a sufficient heat exchange with the heat exchangers 11, 13, 15; thus, heat received by the heat exchangers 11, 13, 15 from the CPU via the heat pipe assembly 20 and the heat conducting plates 110, 130, 150 can be quickly and efficiently dissipated to atmosphere by the airflow.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A heat sink assembly for a heat-generating electronic component, comprising:
a base adapted for thermally connecting with the electronic component;
a main heat exchanger comprising a heat conducting plate formed on the base and a plurality of fins arranged a top of the heat conducting plate;
a shell mounted on the base and surrounding the main heat exchanger; and
a heat pipe thermally connecting the base and the main heat exchanger, adapted for transferring heat from the heat-generating electronic component to the main heat exchanger for dissipation of the heat.

2. The heat sink assembly of claim 1, wherein the main heat exchanger comprises a core formed on a top of the heat conducting plate and the fins extend radially outwardly from the core.

3. The heat sink assembly of claim 2, wherein the heat pipe comprises an evaporating portion located at a bottom of the base, adapted for contacting with the heat-generating electronic component, and a condensing portion received in the core of the main heat exchanger.

4. The heat sink assembly of claim 1, wherein the fins are curved in a similar direction.

5. The heat sink assembly of claim 1, wherein a pair of plates extend perpendicularly and upwardly from the base, and an arched cover connects the plates to form the shell.

6. The heat sink assembly of claim 5, wherein the cover connects the plates at middle portions thereof.

7. The heat sink assembly of claim 5, wherein the shell has a C-shaped configuration.

8. The heat sink assembly of claim 1, wherein a pair of additional heat exchangers are symmetrically formed at flanks of the main heat exchanger and surrounded by the shell.

9. The heat sink assembly of claim 8, wherein the additional heat exchangers comprise conducting plates slantwise, symmetrically arranged at the flanks of the heat conducting plate of the main heat exchanger, cores formed on tops of the heat conducting plates of the additional heat exchangers and curved fins arranged about the cores of the additional heat exchangers.

10. The heat sink assembly of claim 9, wherein the cores of the additional exchangers are located below the core of the main heat exchanger.

11. The heat sink assembly of claim 9, wherein three heat pipes connect the base and the cores of the main and additional heat exchangers.

12. The heat sink assembly of claim 1, wherein the three heat pipes comprise evaporating portions in contact with the base and condensing portions inserted in corresponding cores of the main and additional heat exchangers.

13. The heat sink assembly of claim 1, wherein the shell has two opposite open ends, and the heat conducting plate of the main heat exchangers extends from one of open ends to the other open end.

14. A heat sink assembly comprising:
a heat sink having a base adapted for thermally connecting with an electronic component and a shell having two ends connecting the base to form a pair of opposite open ends, the heat sink comprising a plurality of heat exchangers surrounded by the shell, each of the heat exchangers having a heat conducting plate formed on the base and a set of fins formed on a top of the heat conducting plate; and
a plurality of heat pipes connecting the base and the heat exchangers.

15. The heat sink assembly of claim 14, wherein the heat exchangers comprise a main heat exchanger formed on a center of the base and a pair of second heat exchangers symmetrically formed at flanks of the main heat exchanger.

16. The heat sink assembly of claim 14, the base forms a protrusion block at bottom thereof adapted for contacting with the electronic component, and the protrusion block defines a plurality of grooves at a bottom thereof.

17. The heat sink assembly of claim 16, wherein the heat pipes comprise evaporating portions received in the grooves of the protrusion block adapted for directly contacting with the electronic component, and condensing portions inserted in the tops of the heat conducting plates of the heat exchangers and surrounded by the fins.

18. The heat sink assembly of claim 14, wherein the set of fins extend radially and outwardly from the top of the heat conducting plate of each of the heat exchangers.
